(19) United States
(12) Patent Application Publication
(10) Pub. No.: US 2026/0269183 A1
(43) Pub. Date: Sep. 10, 2026

(54) POWER SUPPLY SYSTEM, PLASMA PROCESSING APPARATUS, AND CONTROL METHOD

(71) Applicant: Tokyo Electron Limited, Tokyo (JP)

(72) Inventors: Yuto KOSAKA, Miyagi (JP); Chishio KOSHIMIZU, Miyagi (JP)

(73) Assignee: Tokyo Electron Limited, Tokyo (JP)

(21) Appl. No.: 19/663,323

(22) Filed: Apr. 30, 2026

Related U.S. Application Data
(63) Continuation of application No. PCT/JP2024/039312, filed on Nov. 5, 2024.

(30) Foreign Application Priority Data
Nov. 14, 2023 (JP) 2023-193430

(51) Int. Cl. H01J 37/32

(52) U.S. Cl. CPC H01J 37/32128; H01J 37/32155

(57) ABSTRACT

A power supply system of a plasma processing apparatus includes a radio frequency power supply, a bias power supply, and a power supply circuitry. The radio frequency power supply generates radio frequency power for plasma generation. The bias power supply supplies an electric bias to a substrate support. The power supply circuitry determines respective frequencies of the radio frequency power for a plurality of designated phase periods among a plurality of phase periods within a waveform cycle of the electric bias to suppress reflection of the radio frequency power. The power supply circuitry determines respective frequencies of the radio frequency power for phase periods, other than the plurality of designated phase periods, among the plurality of phase periods by interpolation using the respective frequencies of the radio frequency power for the plurality of designated phase periods.

### CROSS-REFERENCE TO RELATED APPLICATIONS

This application is a continuation application of PCT Application No. PCT/JP2024/039312, filed on Nov. 5, 2024, which claims the benefit of priority from Japanese Patent Application No. 2023-193430, filed on Nov. 14, 2023. The entire contents of the above listed PCT and priority applications are incorporated herein by reference.

### BACKGROUND

### Field

Example embodiments of the present disclosure relate to a power supply system, a plasma processing apparatus, and a control method.

### Description of the Related Art

### SUMMARY

In one example embodiment, a plasma processing apparatus is provided. The plasma processing apparatus includes a chamber, a substrate support, and a power supply system. The substrate support is disposed in the chamber. The power supply system includes a radio frequency power supply, a bias power supply, and a power supply circuitry. The radio frequency power supply is configured to supply radio frequency power to generate plasma in the chamber. The bias power supply is configured to repeatedly supply an electric bias to the substrate support at a time interval of a waveform cycle to attract ions from the plasma to a substrate on the substrate support. The waveform cycle includes a plurality of phase periods, and the plurality of phase periods includes a plurality of designated phase periods of which a total number is less than a total number of the plurality of phase periods. The power supply circuitry determines respective frequencies of the radio frequency power for the plurality of designated phase periods by adjusting the frequency of the radio frequency power for an m-th designated phase period among the plurality of designated phase periods within an i-th waveform cycle in a sequence of waveform cycles so as to suppress reflection of the radio frequency power, based on a change in the frequency of the radio frequency power for the m-th designated phase period and a change in a degree of reflection of the radio frequency power prior to the i-th waveform cycle in the sequence. The power supply circuitry determines respective frequencies of the radio frequency power for phase periods, other than the plurality of designated phase periods, among the plurality of phase periods within the i-th waveform cycle by interpolation using the respective frequencies of the radio frequency power for the plurality of designated phase periods.

### BRIEF DESCRIPTION OF THE DRAWINGS

FIG. 1 is a diagram for explaining a configuration example of a plasma processing system.

FIG. 2 is a diagram for explaining a configuration example of a capacitively coupled plasma processing apparatus.

FIG. 3 is a diagram illustrating an example of a waveform of an electric bias.

Each of FIG. 4A and FIG. 4B is a timing chart of an example of source radio frequency power and an electric bias in a plasma processing apparatus according to one example embodiment.

FIG. 5A is a flowchart of a control method according to one example embodiment, and FIG. 5B is a flowchart of step STa illustrated in FIG. 5A.

FIG. 6 is a timing chart related to a power supply system according to one example embodiment.

FIG. 7 is a timing chart related to a power supply system according to one example embodiment.

FIG. 8 is a flowchart illustrating an example of processing in step STc illustrated in FIG. 5B.

FIG. 9 is a flowchart illustrating an example of processing in step ST9 illustrated in FIG. 8.

FIG. 10 is a flowchart illustrating another example of processing in step STc illustrated in FIG. 5B.

FIG. 11 is a flowchart illustrating an example of processing in step ST9a illustrated in FIG. 10.

FIG. 12 is a timing chart of an example of source radio frequency power and an electric bias in a plasma processing apparatus according to one example embodiment.

### DETAILED DESCRIPTION

Hereinafter, various example embodiments will be described in detail with reference to the drawings. In the drawings, the same or equivalent portions are denoted by the same reference signs.

A plasma processing apparatus is used in plasma processing of a substrate. In the plasma processing apparatus, bias radio frequency power is used to attract ions from plasma generated in a chamber to a substrate. Japanese Unexamined Patent Publication No. 2009-246091 discloses a plasma processing apparatus that modulates the power level and frequency of bias radio frequency power.

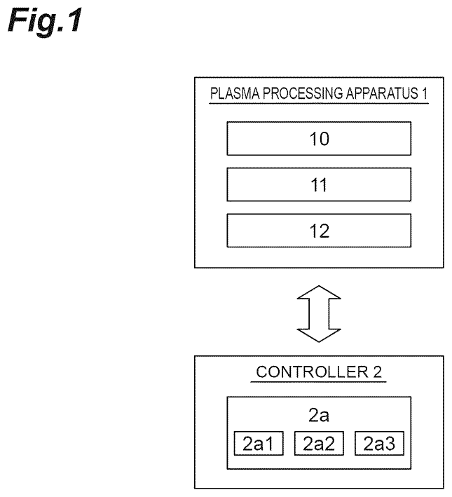

FIG. 1 illustrates an example configuration of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in the plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP).

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2a1, a storage 2a2, and a communication interface 2a3. The controller 2 is implemented in, for example, a computer 2a. The processor 2a1 may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2a1 reads the program from the storage 2a2 to execute the program. The medium may be of any type which can be accessed by the computer 2a or may be a communication line connected to the communication interface 2a3. The processor 2a1 may be a programmable logic device such as a central processing unit (CPU) or a field-programmable gate array (FPGA). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

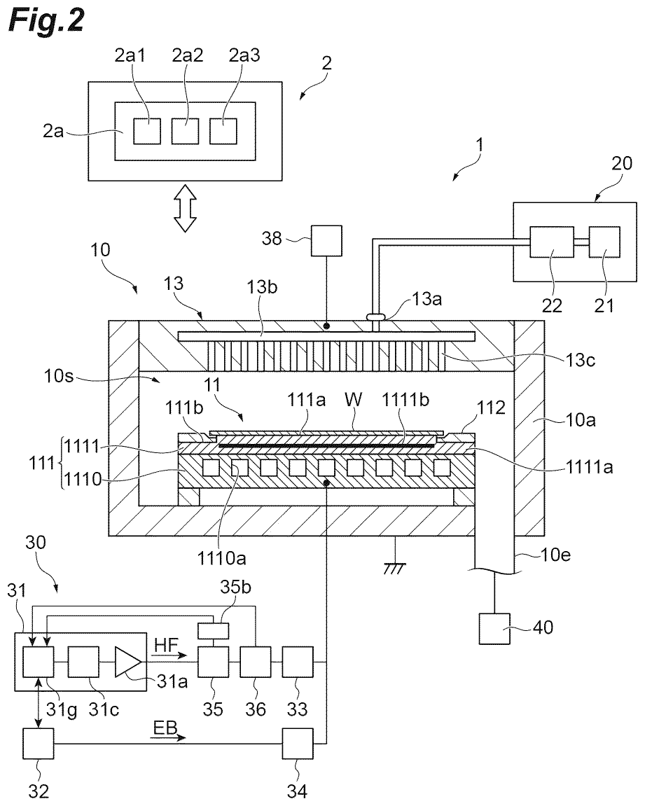

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, a power supply system 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in the plasma processing chamber 10. The showerhead 13 is disposed above the substrate support 11. In an embodiment, the showerhead 13 forms at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The substrate support 11 is electrically insulated from the housing of the plasma processing chamber 10.

The substrate support 11 includes a body 111 and a ring assembly 112. The body 111 has a central region 111a for supporting a substrate W and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the ring assembly 112.

In an embodiment, the body 111 includes a base 1110 and an electrostatic chuck 1111. The base 1110 includes a conductive member. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In an embodiment, the ceramic member 1111a also has the annular region 111b. Any other member, such as an annular electrostatic chuck or an annular insulating member, surrounding the electrostatic chuck 1111 may have the annular region 111b. In this case, the ring assembly 112 may be disposed on either the annular electrostatic chuck or the annular insulating member, or both the electrostatic chuck 1111 and the annular insulating member.

The ring assembly 112 includes one or more annular members. In an embodiment, the annular members include one or more edge rings and at least one cover ring. The edge ring is composed of a conductive or insulating material, whereas the cover ring is composed of an insulating material.

The substrate support 11 may also include a temperature adjusting module that is configured to adjust at least one of the electrostatic chuck 1111, the ring assembly 112, and the substrate to a target temperature. The temperature adjusting module may be a heater, a heat transfer medium, a flow passage 1110a, or any combination thereof. A heat transfer fluid, such as brine or gas, flows through the flow passage 1110a. In an embodiment, the flow passage 1110a is formed in the base 1110, and one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors (SGIs) provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include at least one flow modulation device that can modulate or pulse the flow of the at least one process gas.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

The power supply system 30 includes a radio frequency power supply 31 and a bias power supply 32. The radio frequency power supply 31 configures the plasma generator 12 of one embodiment. The radio frequency power supply 31 is configured to generate source radio frequency power. In the following description, the radio frequency power generated by the radio frequency power supply 31 is referred to as source radio frequency power HF. The source radio frequency power HF has a frequency. In the following description, the frequency of the source radio frequency power HF is referred to as a source frequency. The source radio frequency power HF has a sinusoidal waveform of which a frequency is the source frequency. The source frequency may be a frequency in the range of 10 MHz to 150 MHz.

The radio frequency power supply 31 is electrically connected to a radio frequency electrode via a matching unit 33, and is configured to supply the source radio frequency power HF to the radio frequency electrode. The radio frequency electrode may be disposed in the substrate support 11. The radio frequency electrode may be the conductive member of the base 1110 or at least one electrode disposed in the ceramic member 1111a. Alternatively, the radio frequency electrode may be an upper electrode. When the source radio frequency power HF is supplied to the radio frequency electrode, plasma is generated from the gas in the chamber 10.

The matching unit 33 has a variable impedance. The variable impedance of the matching unit 33 is set so as to reduce reflection of the source radio frequency power HF from the load. The matching unit 33 may be controlled by, for example, the controller 2.

In an embodiment, the radio frequency power supply 31 may include a signal generator 31g, a D/A converter 31c, and an amplifier 31a. The signal generator 31g generates a radio frequency signal having a source frequency f. The signal generator 31g may be configured with a programmable processor or a programmable logic device such as an FPGA (Field-Programmable Gate Array).

The output of the signal generator 31g is connected to the input of the D/A converter 31c. The D/A converter 31c converts the radio frequency signal from the signal generator 31g into an analog signal. The output of the D/A converter 31c is connected to the input of the amplifier 31a. The amplifier 31a amplifies the analog signal from the D/A converter 31c to generate the source radio frequency power HF. The gain of the amplifier 31a is specified to the radio frequency power supply 31 by the controller 2. The radio frequency power supply 31 need not include the D/A converter 31c. In this case, the output of the signal generator 31g is connected to the input of the amplifier 31a, and the amplifier 31a amplifies the radio frequency signal from the signal generator 31g to generate the source radio frequency power HF.

The bias power supply 32 is electrically coupled to the substrate support 11. The bias power supply 32 is electrically connected to a bias electrode in the substrate support 11 and is configured to supply an electric bias EB to the bias electrode. The bias electrode may be the conductive member of the base 1110 or at least one electrode disposed in the ceramic member 1111a. The bias electrode may be shared with the radio frequency electrode. When the electric bias EB is supplied to the bias electrode, ions from the plasma are attracted to the substrate W.

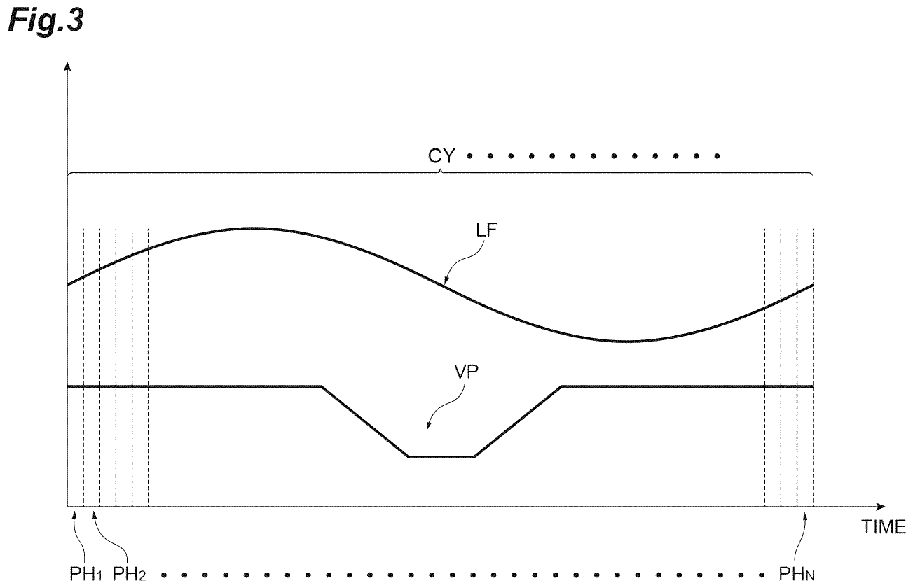

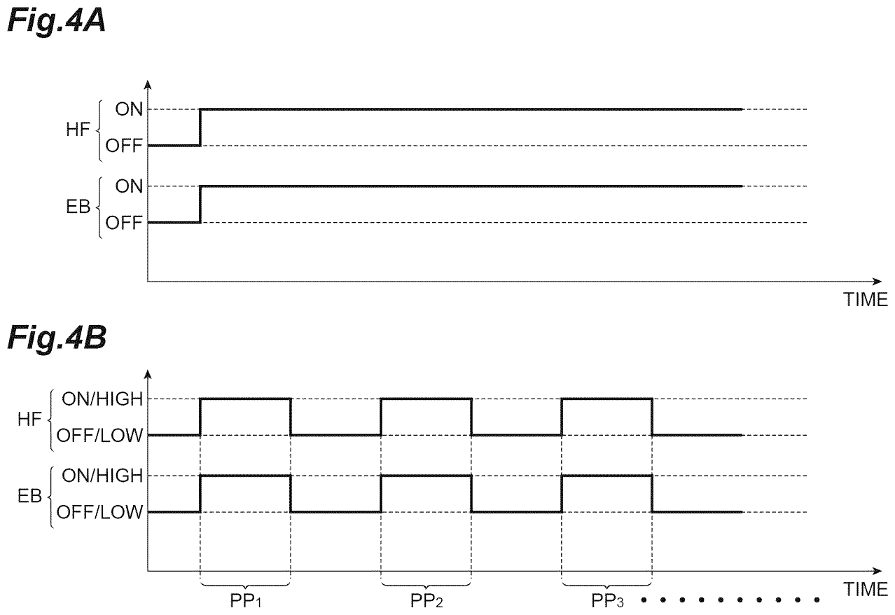

Hereinafter, reference is made to FIG. 3 together with FIG. 2. FIG. 3 is a diagram illustrating an example of a waveform of an electric bias. The bias power supply 32 is configured to periodically apply an electric bias EB having a waveform cycle CY to the bias electrode. That is, the electric bias EB is applied to the bias electrode in each of a plurality of waveform cycles CY that are repetitions of the waveform cycle CY. The waveform cycle CY is defined by a bias frequency. The bias frequency is, for example, a frequency of 50 kHz or more and 27 MHz or less. The time length of the waveform cycle CY is the reciprocal of the bias frequency.

The electric bias EB may be a bias radio frequency power LF having a bias frequency. That is, the electric bias EB may have a sinusoidal waveform of which a frequency is the bias frequency. In this case, the bias power supply 32 is electrically connected to the bias electrode via a matching unit 34. The variable impedance of the matching unit 34 is set so as to reduce reflection of the bias radio frequency power LF from the load.

Alternatively, the electric bias EB may include a voltage pulse VP. The voltage pulse VP is applied to the bias electrode within the waveform cycle CY. The voltage pulse VP is periodically applied to the bias electrode at a time interval equal to the time length of the waveform cycle CY. The waveform of the voltage pulse VP may be a rectangular wave, a triangular wave, or any waveform. The polarity of the voltage of the voltage pulse VP is set so as to create a potential difference between the substrate W and the plasma to attract ions from the plasma to the substrate W. The voltage pulse VP is applied to the bias electrode such that the waveform cycle CY includes a period during which the potential of the substrate W is a negative potential. The voltage pulse VP applied to the bias electrode may have a negative potential, may have a positive potential, or may have a potential that varies between a positive potential and a negative potential. The voltage pulse VP may be a negative voltage pulse or a negative DC voltage pulse. When the electric bias EB is the voltage pulse VP, the plasma processing apparatus 1 need not include the matching unit 34.

As illustrated in FIG. 2, the plasma processing apparatus 1 may further include a sensor 35 and/or a sensor 36. The sensor 35 is configured to measure a power level Pr of a reflected wave of the source radio frequency power HF from the load. The sensor 35 includes, for example, a directional coupler. The directional coupler may be disposed between the radio frequency power supply 31 and the matching unit 33. The sensor 35 may further be configured to measure a power level Pf of a forward wave of the source radio frequency power HF. The power level Pr of the reflected wave measured by the sensor 35 is notified to the radio frequency power supply 31. In addition, the power level Pf of the forward wave may be notified from the sensor 35 to the radio frequency power supply 31. The sensor 35 may notify the radio frequency power supply 31 of the reflectance, i.e., Pr/Pf. The reflectance may be determined from the power level Pf and the power level Pr in the radio frequency power supply 31. A detection circuit 35b may be connected between the sensor 35 and the radio frequency power supply 31, and the power level Pf and the power level Pr may be determined from the output of the detection circuit 35b.

The sensor 36 includes a voltage sensor and a current sensor. The sensor 36 is configured to measure a voltage V_{S} and a current I_{S} in a power feed path connecting the radio frequency power supply 31 and the radio frequency electrode to each other. The source radio frequency power HF is supplied to the radio frequency electrode via this power feed path. The sensor 36 may be provided between the radio frequency power supply 31 and the matching unit 33. The voltage V_{S} and the current I_{S} are notified to the radio frequency power supply 31. The sensor 36 may notify the radio frequency power supply 31 of an impedance Z_{L} of the load of the radio frequency power supply 31 determined from the voltage V_{S} and the current I_{S}. The impedance Z_{L} may be determined from the voltage V_{S} and the current I_{S} in the radio frequency power supply 31. The sensor 36 may notify the radio frequency power supply 31 of a phase difference θ between the voltage V_{S} and the current I_{S}. The phase difference θ may be determined from the voltage V_{S} and the current I_{S} in the radio frequency power supply 31. The sensor 36 may notify the radio frequency power supply 31 of a reflection coefficient Γ determined from the voltage V_{S} and the current I_{S}. The reflection coefficient Γ may be determined from the voltage V_{S} and the current I_{S} in the radio frequency power supply 31.

The power supply system 30 may further include a DC power supply 38. The DC power supply 38 is configured to apply a DC voltage DCS to the upper electrode (e.g., the showerhead 13). The DC power supply 38 may apply a negative DC voltage to the upper electrode. The DC power supply 38 may be a variable DC power supply.

Hereinafter, reference is made to FIG. 4A and FIG. 4B together with FIG. 2 and FIG. 3. Each of FIG. 4A and FIG. 4B is a timing chart of an example of source radio frequency power and an electric bias in a plasma processing apparatus according to one example embodiment. In these figures, “ON” of the source radio frequency power HF indicates that the source radio frequency power HF is being supplied, and “OFF” of the source radio frequency power HF indicates that the supply of the source radio frequency power HF is stopped. In FIG. 4B, “HIGH” of the source radio frequency power HF indicates that the source radio frequency power HF having a power level higher than the power level indicated by “LOW” is being supplied. In these figures, “ON” of the electric bias EB indicates that the electric bias EB is being supplied, and “OFF” of the electric bias EB indicates that the supply of the electric bias EB is stopped. In FIG. 4B, “HIGH” of the electric bias EB indicates that the electric bias EB having a level higher than the level indicated by “LOW” is being supplied. When the electric bias EB is the bias radio frequency power LF, the level of the electric bias EB is the power level of the bias radio frequency power LF. When the electric bias EB includes the voltage pulse VP, the electric bias EB has a higher level as the energy of ions attracted to the substrate W becomes higher. When the electric bias EB includes the voltage pulse VP, the level of the electric bias EB may be the absolute value of the voltage level of the voltage pulse VP in the negative direction with respect to a reference voltage (for example, 0 V).

The radio frequency power supply 31 is configured to supply the source radio frequency power HF in parallel with the periodic supply of the electric bias EB from the bias power supply 32. That is, as illustrated in FIG. 4A, the electric bias EB and the source radio frequency power HF may be supplied simultaneously and continuously from the start to the end of the process.

Alternatively, as illustrated in FIG. 4B, pulses of the electric bias EB and pulses of the source radio frequency power HF may be supplied in synchronization with each other. That is, in each of pulse periods PP₁, PP₂, PP₃, . . . (i.e., a plurality of pulse periods PP), pulses of the electric bias EB and pulses of the source radio frequency power HF may be supplied simultaneously. Each of the plurality of pulse periods PP includes a plurality of waveform cycles CY. That is, in each of the plurality of pulse periods PP, the electric bias EB is periodically supplied. The pulses of the electric bias EB may be ON/OFF pulses that alternately take a supply state (ON state in FIG. 4B) and a stop state (OFF state in FIG. 4B). Alternatively, the pulses of the electric bias EB may be HIGH/LOW pulses that alternately take a high-level state (HIGH state in FIG. 4B) and a LOW-level state (LOW state in FIG. 4B). The pulses of the source radio frequency power HF may also be ON/OFF pulses that alternately take a supply state (ON state in FIG. 4B) and a stop state (OFF state in FIG. 4B). Alternatively, the pulses of the source radio frequency power HF may be HIGH/LOW pulses that alternately take a high-level state (HIGH state in FIG. 4B) and a LOW-level state (LOW state in FIG. 4B). The power level of the source radio frequency power HF may also be modulated during a period in which the source radio frequency power HF is ON. The power level of the source radio frequency power HF may also be modulated during a period in which the power level of the source radio frequency power HF is HIGH. The power level of the source radio frequency power HF may also be modulated during a period in which the power level of the source radio frequency power HF is LOW.

The radio frequency power supply 31 is configured to adjust the source frequency of the source radio frequency power HF for each of a plurality of phase periods PH within each waveform cycle CY in order to suppress reflection of the source radio frequency power HF from the load. The plurality of phase periods PH are a plurality of periods that divide the waveform cycle CY. As illustrated in FIG. 3, each waveform cycle CY is divided into phase periods PH₁ to PH_{N} as the plurality of phase periods PH. “N” is a total number of phase periods in each waveform cycle CY.

The adjustment of the source frequency in the radio frequency power supply 31 may be performed by adjusting the frequency of the radio frequency signal by the signal generator 31g. The source frequency is determined in the power supply controller. The power supply controller may be provided inside the radio frequency power supply 31 or may be provided outside the radio frequency power supply 31. The signal generator 31g may function as the power supply controller, or another device inside the radio frequency power supply 31 may function as the power supply controller. Alternatively, the controller 2 may function as the power supply controller.

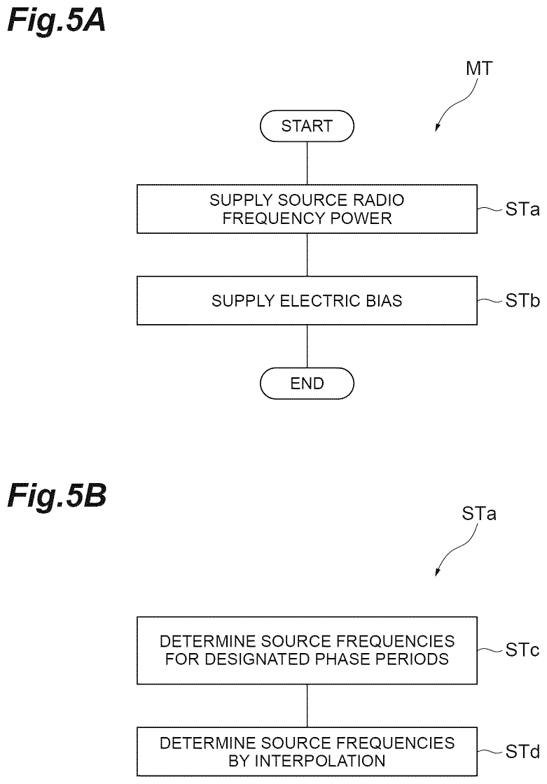

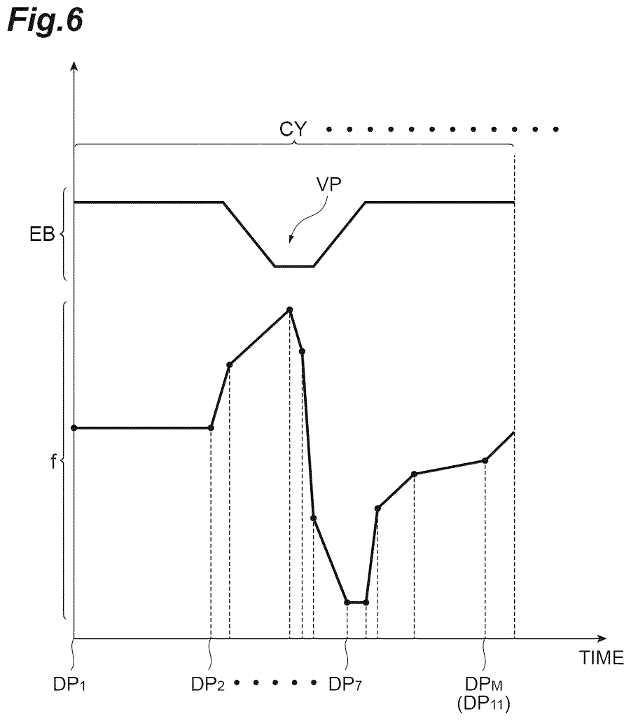

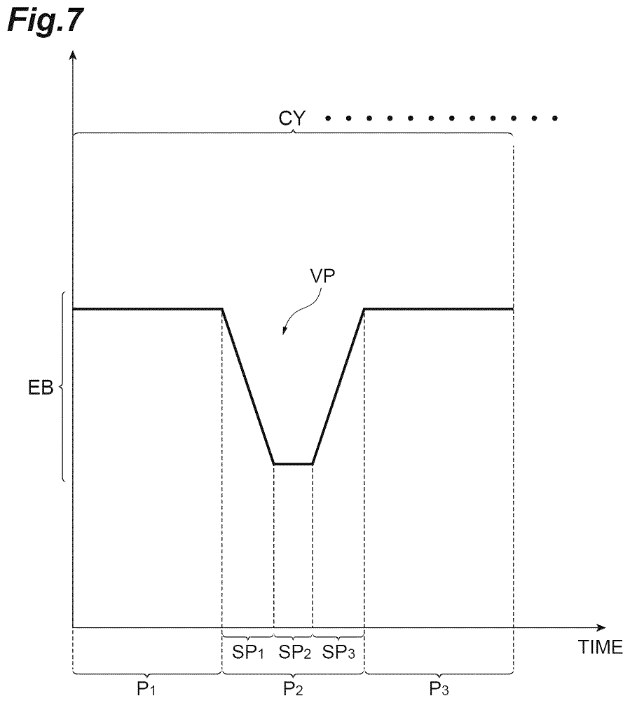

Hereinafter, a control method for the source frequency will be described with reference to FIG. 5A, FIG. 5B, FIG. 6, and FIG. 7. Processing related to the determination of the source frequency by the power supply controller will also be described. FIG. 5A is a flowchart of a control method according to one example embodiment, and FIG. 5B is a flowchart of step STa illustrated in FIG. 5A. Each of FIG. 6 and FIG. 7 is a timing chart related to a power supply system according to one example embodiment.

The control method illustrated in FIG. 5A (hereinafter referred to as “method MT”) includes steps STa and STb. In step STa, the source radio frequency power HF is supplied from the radio frequency power supply 31 to the radio frequency electrode in order to generate plasma from gas in the chamber 10. In step STb, the electric bias EB is repeatedly supplied to the substrate support 11 at a time interval of the waveform cycle CY in order to attract ions from the plasma to the substrate W on the substrate support 11. In steps STa and STb, as illustrated in FIG. 4A, the source radio frequency power HF and the electric bias EB may be supplied simultaneously and continuously. Alternatively, as illustrated in FIG. 4B, pulses of the source radio frequency power HF and pulses of the electric bias EB may be supplied in synchronization with each other.

As illustrated in FIG. 5B, step STa includes steps STc and STd. In steps STc and STd, the power supply controller determines the source frequencies f of the source radio frequency power HF supplied in the plurality of phase periods PH within the waveform cycle CY. As illustrated in FIG. 6, the plurality of phase periods PH within the waveform cycle CY includes a plurality of designated phase periods DP. A total number of the plurality of designated phase periods DP within the waveform cycle CY is M. M is less than N, which is the total number of the plurality of phase periods PH within the waveform cycle CY. The number M of the plurality of designated phase periods DP within the waveform cycle CY is 11 in the example of FIG. 6, but the number M is not limited to 11.

In step STc, the power supply controller determines the source frequencies f for the plurality of designated phase periods DP within the waveform cycle CY by performing feedback processing in a sequence CYS of waveform cycles CY. The feedback processing will be described later. In step STd, the power supply controller determines the source frequencies f for phase periods, other than the plurality of designated phase periods DP, among the plurality of phase periods PH within the waveform cycle CY by interpolation using the source frequencies f for the plurality of designated phase periods DP. The interpolation may be linear interpolation using the source frequencies f for two adjacent designated phase periods DP. The interpolation may also be interpolation by another method.

The interval of the plurality of designated phase periods DP within the waveform cycle CY may be set to be smaller in a section within the waveform cycle CY where the change in the potential of the substrate W is large, than the interval in a section within the waveform cycle CY where the change in the potential of the substrate W is small.

The phase of each of the plurality of designated phase periods DP in the waveform cycle CY may be predetermined. As illustrated in FIG. 7, when the electric bias EB includes the voltage pulse VP, the waveform cycle CY may include a first period P₁, a second period P₂, and a third period P₃. The voltage pulse VP is in an OFF state during the first period P₁. The second period P₂ follows the first period P₁. The voltage pulse VP is in an ON state during the second period P₂. The third period P₃ follows the second period P₂. The voltage pulse VP is in an OFF state during the third period P₃.

In an embodiment, the plurality of designated phase periods DP may be predetermined such that the interval thereof in the second period P₂ is smaller than the interval of the plurality of designated phase periods DP in each of the first period P₁ and the third period P₃. In this case, in the second period P₂ where the potential of the substrate changes significantly, the source frequency f can be adjusted so as to more effectively suppress reflection of the source radio frequency power HF.

In an embodiment, the interval of the plurality of designated phase periods DP in the third period P₃ may be the same as the interval of the plurality of designated phase periods DP in the first period P₁, or may be smaller than the interval of the plurality of designated phase periods DP in the first period P₁. When the interval of the plurality of designated phase periods DP in the third period P₃ is smaller than the interval of the plurality of designated phase periods DP in the first period P₁, the source frequency f can be adjusted so as to more effectively suppress reflection of the source radio frequency power HF immediately after the voltage pulse VP switches from the ON state to the OFF state.

In an embodiment, the second period P₂ may include a first sub-period SP₁, a second sub-period SP₂, and a third sub-period SP₃. The first sub-period SP₁ is a period immediately following the first period P₁. In the first sub-period SP₁, the voltage level of the voltage pulse VP changes in the negative direction from its reference voltage level (for example, 0 V) to a set voltage level. The second sub-period SP₂ follows the first sub-period SP₁. In the second sub-period SP₂, the voltage level of the voltage pulse VP is at the set voltage level thereof. The third sub-period SP₃ follows the second sub-period SP₂. In the third sub-period SP₃, the voltage level of the voltage pulse VP changes from its set voltage level to the reference voltage level. The intervals of the plurality of designated phase periods DP in each of the first sub-period SP₁, the second sub-period SP₂, and the third sub-period SP₃ may be the same as or different from each other.

In an embodiment, the plurality of designated phase periods DP may be determined in advance from the source frequencies f for the plurality of phase periods PH within the waveform cycle CY obtained by performing the feedback processing described below for each phase period PH in the sequence CYS of waveform cycles CY. Specifically, the plurality of designated phase periods DP may be selected in advance from the plurality of phase periods PH so as to exclude a phase period PHₙ when each of the absolute value of the difference between the source frequency f[n] of the n-th phase period PHₙ within the waveform cycle CY and the source frequency f[n−u] of the (n−u)-th phase period PHₙ₋ᵤ within the waveform cycle CY and the absolute value of the difference between the source frequency f[n] and the source frequency f[n+u] of the (n+u)-th phase period PHₙ₊ᵤ within the waveform cycle CY is greater than a predetermined value, and both the source frequency f[n−u] and the source frequency f[n+u] are greater or smaller than the source frequency f[n].

The plurality of designated phase periods DP may also be determined by calculation by the power supply controller. In an embodiment, the power supply controller acquires, in a preparation period, a sequence of source frequencies f for the plurality of phase periods PH within the waveform cycle CY obtained by performing the feedback processing described below for each phase period PH in the sequence CYS of waveform cycles CY. The power supply controller determines the plurality of designated phase periods DP such that the larger the change in the source frequency f in a section in the sequence of source frequencies f obtained by smoothing the sequence of source frequencies f, the smaller the interval between the plurality of designated phase periods DP.

In an embodiment, the power supply controller may acquire the voltage waveform of the electric bias EB. In this embodiment, the power supply controller may identify the above-described first period P₁, second period P₂, and third period P₃ from the acquired voltage waveform, and may set the intervals of the plurality of designated phase periods DP in each of the first period P₁, the second period P₂, and the third period P₃ as described above.

Hereinafter, the feedback processing for determining the source frequency f for each of the plurality of designated phase periods DP in step STc will be described. The power supply controller determines the source frequency f[i,m] for the m-th designated phase period DPₘ within the i-th waveform cycle CYᵢ in the sequence CYS of waveform cycles CY so as to suppress the degree of reflection, based on the change in the source frequency and the degree of reflection of the source radio frequency power of the m-th designated phase period DPₘ within preceding waveform cycles CY in the sequence CYS. The waveform cycles CY preceding the waveform cycle CYᵢ in the sequence CYS may include waveform cycles CY_{i-Ifb} and CY_{i-2×Ifb}. Here, “Ifb” is an integer of 1 or more.

The feedback processing includes first feedback processing and/or second feedback processing. The first feedback processing is applied when the source radio frequency power HF and the electric bias EB are supplied simultaneously and continuously as illustrated in FIG. 4A. In the first feedback processing, the sequence CYS is composed of a plurality of waveform cycles CY that repeat continuously.

The second feedback processing is applied when pulses of the source radio frequency power HF and pulses of the electric bias EB synchronized with each other are supplied as illustrated in FIG. 4B. In the second feedback processing, the sequence CYS is composed of waveform cycles CY of the same order in each of the plurality of pulse periods PP, i.e., the k-th waveform cycle CYₖ in each of the plurality of pulse periods PP. In the case of the example illustrated in FIG. 4B, the second feedback processing may be applied to all waveform cycles CY in each of the plurality of pulse periods PP. Alternatively, the second feedback processing may be applied to each of the 1st through K₁-th waveform cycles CY in each of the plurality of pulse periods PP, and the first feedback processing may be applied to each of the (K₁+1)-th through last waveform cycles CY in each of the plurality of pulse periods PP. K₁ is an integer of 1 or more. Alternatively, the second feedback processing may be applied to each of the 1st through K₁-th waveform cycles CY in each of the plurality of pulse periods PP, and in each of the (K₁+1)-th through last waveform cycles CY in each of the plurality of pulse periods PP, the source frequency of each designated phase period of the K₁-th waveform cycle CY may be used in the same designated phase period.

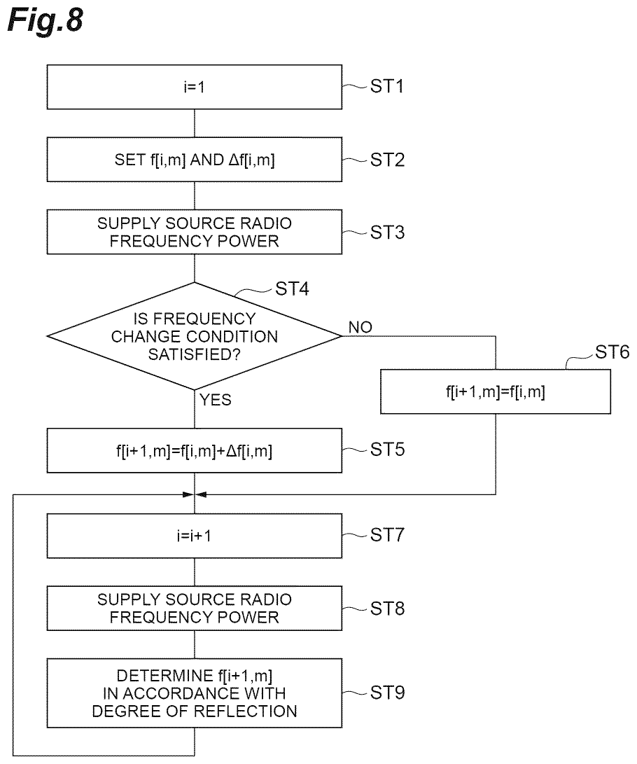

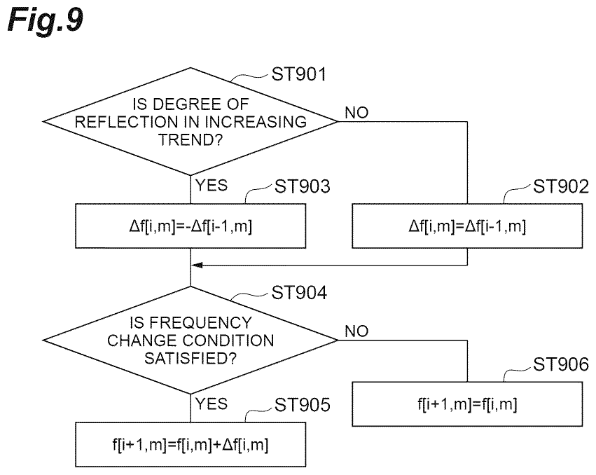

Hereinafter, an example of the feedback processing in step STc will be described with reference to FIG. 8 and FIG. 9. FIG. 8 is a flowchart illustrating an example of processing in step STc illustrated in FIG. 5B. FIG. 9 is a flowchart illustrating an example of processing in step ST9 illustrated in FIG. 8. The example of the feedback processing described below is an example in which the above-described “Ifb” is 1. However, as described above, “Ifb” may be an integer greater than 1.

As illustrated in FIG. 8, step STa may include steps ST1 through ST9. Steps ST1 through ST9 are performed for each of the plurality of designated phase periods DP within each waveform cycle CY in the sequence CYS, i.e., each of designated phase periods DP₁ through DP_{M}.

In step ST1, the power supply controller sets i to 1. “i” represents the order of the waveform cycle CY within the sequence CYS. In the subsequent step ST2, the power supply controller sets the source frequency f[i,m] and the shift value Δf[i,m]. In step ST2, the source frequency f[i,m] and the shift value Δf[i,m], i.e., the source frequency f[1,m] and the shift value Δf[1,m], are set to their respective preset values.

In the subsequent step ST3, the power supply controller supplies the source radio frequency power HF having the source frequency f[i,m] from the radio frequency power supply 31 in the m-th designated phase period DPₘ within the waveform cycle CYᵢ in the sequence CYS.

In the subsequent step ST4, the power supply controller determines whether the degree of reflection P_{d}[i,m] of the source radio frequency power HF in the designated phase period DPₘ within the waveform cycle CYᵢ in the sequence CYS is large enough to satisfy a frequency change condition. In step ST4, the frequency change condition is satisfied when the degree of reflection P_{d}[i,m] of the source radio frequency power HF in the designated phase period DPₘ within the waveform cycle CYᵢ in the sequence CYS is greater than a threshold value. In step ST4, the frequency change condition may be satisfied when P_{d}[i,m] is greater than a first threshold value Pₜₕ₁[m]. The first threshold values Pₜₕ₁ for the plurality of designated phase periods DP may be the same as or different from each other.

When it is determined in step ST4 that the frequency change condition is satisfied, the power supply controller sets, in step ST5, the source frequency f[i+1,m] for the designated phase period DPₘ within the subsequent waveform cycle CYᵢ₊₁ in the sequence CYS by the following equation.

$$f [ i + 1 , m ] = f [ i , m ] + Δ f [ i , m ]$$

On the other hand, when it is determined in step ST4 that the frequency change condition is not satisfied, the power supply controller sets, in step ST6, the source frequency f[i+1,m] by the following equation.

$$f [ i + 1 , m ] = f [ i , m ]$$

Next, steps ST7 through ST9 are performed. Steps ST7 through ST9 are repeated until a termination instruction is given. In step ST7, the power supply controller increments i by 1. In the subsequent step ST8, the power supply controller supplies the source radio frequency power HF having the source frequency f[i,m] from the radio frequency power supply 31 in the designated phase period DPₘ within the waveform cycle CYᵢ in the sequence CYS.

In the subsequent step ST9, the power supply controller determines the source frequency f[i+1,m] for the designated phase period DPₘ within the next waveform cycle CYᵢ₊₁ in the sequence CYS in accordance with the degree of reflection P_{d}[i,m].

As illustrated in FIG. 9, step ST9 starts with step ST901. In step ST901, the power supply controller determines whether the degree of reflection P_{d}[i,m] shows an increasing trend. In step ST901, the degree of reflection P_{d}[i,m] may be determined to show an increasing trend when P_{d}[i,m]>P_{d}[i−1,m] is satisfied. Alternatively, the degree of reflection P_{d}[i,m] may be determined to show an increasing trend when the degree of reflection in the m-th designated phase period DPₘ shows an increasing trend over two or more waveform cycles CY until the i-th waveform cycle CYᵢ in the sequence CYS.

When it is determined in step ST901 that the degree of reflection P_{d}[i,m] does not show an increasing trend, the power supply controller maintains the sign of the shift value Δf[i,m] in step ST902. That is, the power supply controller sets the shift value Δf[i,m] in step ST902 by the following equation.

$$Δ f [ i , m ] = Δ f [ i - 1 , m ]$$

On the other hand, when it is determined in step ST901 that the degree of reflection P_{d}[i,m] shows an increasing trend, the power supply controller changes the sign of the shift value Δf[i,m] in step ST903. That is, the power supply controller sets the shift value Δf[i,m] in step ST903 by the following equation.

$$Δ f [ i , m ] = - Δ f [ i - 1 , m ]$$

In the subsequent step ST904, the power supply controller determines whether the degree of reflection P_{d}[i,m] of the source radio frequency power HF in the designated phase period DPₘ within the waveform cycle CYᵢ in the sequence CYS is large enough to satisfy the frequency change condition. In step ST904, the frequency change condition is satisfied when the degree of reflection P_{d}[i,m] of the source radio frequency power HF in the designated phase period DPₘ within the waveform cycle CYᵢ in the sequence CYS is greater than a threshold value.

In an embodiment, when it is determined as a result of comparison between the degree of reflection in the designated phase period DPₘ in any waveform cycle within the sequence CYS and the first threshold value Pₜₕ₁[m] that the degree of reflection is small, the frequency change condition need not be satisfied in step ST904 until it is subsequently determined in step ST904 as a result of comparison between the degree of reflection in the designated phase period DPₘ and a second threshold value Pₜₕ₂[m] that the degree of reflection is large. The second threshold value Pₜₕ₂[m] is greater than or equal to the first threshold value Pₜₕ₁[m]. The second threshold value Pₜₕ₂[m] may be greater than the first threshold value Pₜₕ₁[m]. The respective second threshold values Pₜₕ₂[m] for the plurality of designated phase periods DP may be the same as or different from each other.

Specifically, when it is determined that the degree of reflection in the designated phase period DPₘ in any waveform cycle within the sequence CYS is less than or equal to the first threshold value Pₜₕ₁[m], the second threshold value Pₜₕ₂[m] may be used as the threshold value to be compared with the degree of reflection in the designated phase period DPₘ in the subsequent step ST904. Then, when it is determined that the degree of reflection in the designated phase period DPₘ in any waveform cycle within the sequence CYS is greater than the second threshold value Pₜₕ₂[m], the first threshold value Pₜₕ₁[m] may be used as the threshold value to be compared with the degree of reflection in the designated phase period DPₘ in the subsequent step ST904.

When it is determined in step ST904 that the frequency change condition is satisfied, the power supply controller sets, in step ST905, the source frequency f[i+1,m] for the designated phase period DPₘ within the subsequent waveform cycle CYᵢ₊₁ in the sequence CYS by the following equation.

$$f [ i + 1 , m ] = f [ i , m ] + Δ f [ i , m ]$$

On the other hand, when the frequency change condition is not satisfied in step ST904, the power supply controller sets, in step ST906, the source frequency f[i+1,m] by the following equation.

$$f [ i + 1 , m ] = f [ i , m ]$$

In the method MT, reflection of the source radio frequency power HF is suppressed by adjusting the source frequency f[i+1,m] in accordance with the degree of reflection P_{d}[i,m]. In the method MT, the source frequency for the plurality of designated phase periods DP is determined by the above-described feedback processing. In the method MT, the source frequencies for the phase periods, other than the plurality of designated phase periods DP, among the plurality of phase periods PH are determined by interpolation based on the respective source frequencies for the plurality of designated phase periods DP. Therefore, according to the method MT, large variation in the source frequency within the waveform cycle CY is suppressed. As described above, by using the first threshold value Pₜₕ₁ and the second threshold value Pₜₕ₂ in the determination of the frequency change condition, excessive change in the source frequency is suppressed. Furthermore, when the method MT is repeated, high reproducibility of the temporal change in the source frequency can be achieved.

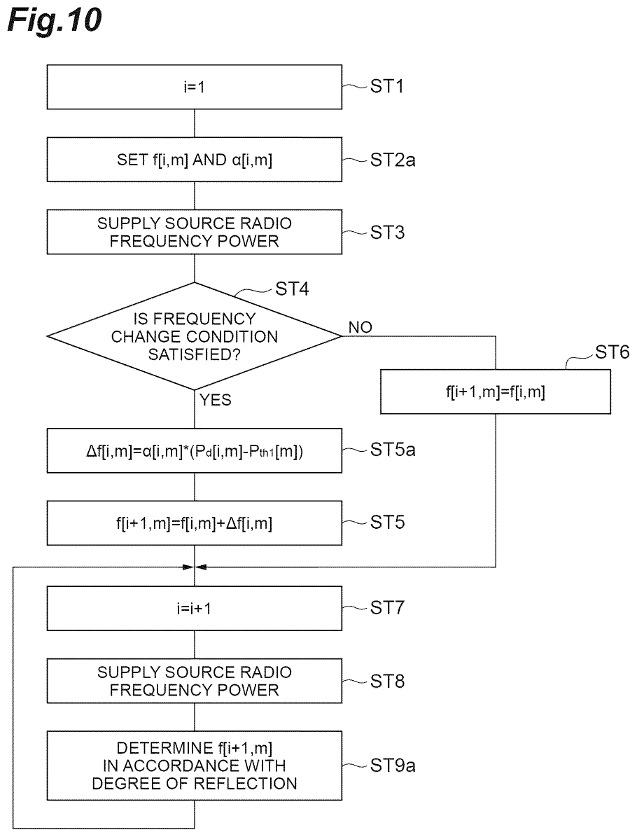

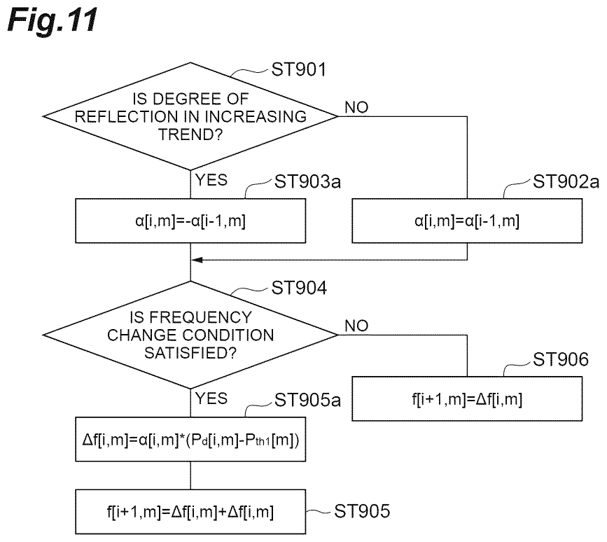

Hereinafter, another example of the processing in step STc will be described with reference to FIG. 10 and FIG. 11. FIG. 10 is a flowchart illustrating another example of processing in step STc illustrated in FIG. 5B. FIG. 11 is a flowchart illustrating an example of processing in step ST9a illustrated in FIG. 10. Hereinafter, the processing in step STc illustrated in FIG. 10 and FIG. 11 will be described from the perspective of differences from the processing illustrated in FIG. 8 and FIG. 9. In the processing illustrated in FIG. 10 and FIG. 11, the power supply controller sets the shift value Δf[i,m] to a value corresponding to the magnitude of the degree of reflection P_{d}[i,m].

Specifically, as illustrated in FIG. 10, the power supply controller sets the source frequency f[i,m] and a coefficient α[i,m] in step ST2a between step ST1 and step ST3. In step ST2a, the source frequency f[i,m] and the coefficient α[i,m], i.e., the source frequency f[1,m] and the coefficient α[1,m], are set to their respective preset values.

When it is determined in step ST4 that the frequency change condition is satisfied, the power supply controller sets the shift value Δf[i,m] in step ST5a between step ST4 and step ST5 by the following equation.

$$Δ f [ i , m ] = α [ i , m ] * ( {P}_{d} [ i , m ] - {P}_{th 1} [ m ] )$$

Then, in step ST9a following step ST8, the power supply controller determines the source frequency f[i+1,m] for the designated phase period DPₘ within the subsequent waveform cycle CYᵢ₊₁ in the sequence CYS in accordance with the degree of reflection P_{d}[i,m].

As illustrated in FIG. 11, step ST9a starts with step ST901. When it is determined in step ST901 that the degree of reflection P_{d}[i,m] does not show an increasing trend, the power supply controller maintains the sign of the coefficient α[i,m] in step ST902a. That is, the power supply controller sets the coefficient α[i,m] in step ST902a by the following equation.

$$α [ i , m ] = α [ i - 1 , m ]$$

On the other hand, when it is determined in step ST901 that the degree of reflection P_{d}[i,m] shows an increasing trend, the power supply controller changes the sign of the coefficient α[i,m] in step ST903a. That is, the power supply controller sets the coefficient α[i,m] in step ST903a by the following equation.

$$α [ i , m ] = - α [ i - 1 , m ]$$

As illustrated in FIG. 11, when it is determined in step ST904 that the frequency change condition is satisfied, the power supply controller sets the shift value Δf[i,m] in step ST905a between step ST904 and step ST905 by the following equation.

$$Δ f [ i , m ] = α [ i , m ] * ( {P}_{d} [ i , m ] - {P}_{th 1} [ m ] )$$

Hereinafter, the degree of reflection P_{d}[i,m] will be described. The degree of reflection P_{d}[i,m] is obtained by acquiring a plurality of evaluation values respectively at a plurality of sample time points in the designated phase period DPₘ within the waveform cycle CYᵢ. The plurality of evaluation values reflect the magnitude of reflection of the source radio frequency power HF respectively at the plurality of sample time points. The number of sample time points in each of the plurality of designated phase periods DP may be the same.

The degree of reflection P_{d}[i,m] is a representative value of the evaluation values respectively at the plurality of sample time points in the designated phase period DPₘ within the waveform cycle CYᵢ. The representative value is an average value of the plurality of evaluation values, a weighted average value of the plurality of evaluation values, or a maximum value of the plurality of evaluation values, or the like. Each of the plurality of evaluation values may be, as a measurement value acquired by the sensors 35, 36, the power level Pr of the reflected wave, the reflectance (i.e., Pr/Pf), the magnitude of the difference between the impedance Z_{L} and the characteristic impedance, or the reflection coefficient Γ. Each of the plurality of evaluation values may be the difference between the resistance value of the transmission system of the source radio frequency power HF as seen from the inlet of the matching unit 33 (i.e., the input of the matching unit 33 on the radio frequency power supply 31 side) or from the radio frequency power supply 31 and a predetermined resistance value (such as 50 Ω). Alternatively, each of the plurality of evaluation values may be the difference between the phase difference between the voltage V_{S} and the current I_{S} at the transmission system of the source radio frequency power HF or at the inlet of the matching unit and a predetermined value (such as 90 degrees).

In an embodiment, the degree of reflection P_{d}[i,m] is a weighted average value of the evaluation values respectively at the plurality of sample time points in the designated phase period DPₘ within the waveform cycle CYᵢ. To obtain the weighted average value, the power supply controller obtains an average value of a plurality of values obtained by multiplying the plurality of evaluation values by a window function. The window function has a weight that decreases in accordance with the time difference from the center of the designated phase period DPₘ. As the window function, a triangular window, a Gaussian window, a Hanning window, a Hamming window, or the like is used. By using the weighted average value obtained with such a window function, it is possible to suppress variation in the calculated value of the degree of reflection P_{d}[i,m] that may be caused by the phase of the source radio frequency power HF in each designated phase period DP.

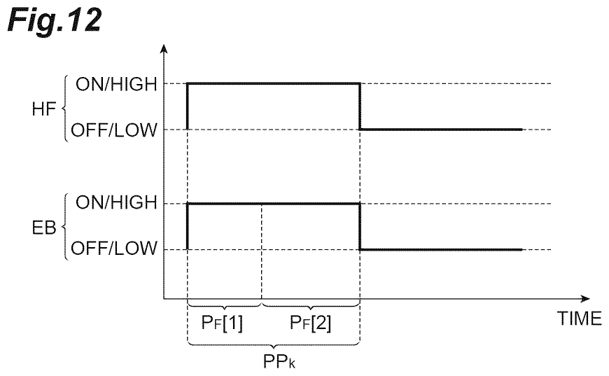

Hereinafter, reference is made to FIG. 12. FIG. 12 is a timing chart of an example of source radio frequency power and an electric bias in a plasma processing apparatus according to one example embodiment. Similar to FIG. 4B, FIG. 12 illustrates an example in which pulses of the electric bias EB and pulses of the source radio frequency power HF are supplied in synchronization with each other. In FIG. 12, a pulse period PPₖ is illustrated among all pulse periods. As illustrated in FIG. 12, each pulse period PP may include a first feedback period P_{F}[1] and a second feedback period P_{F}[2]. The first feedback period P_{F}[1] is a period from the start time point of the pulse period PP to a time point between the start time point and the end time point of the pulse period PP. The second feedback period P_{F}[2] is a period that follows the first feedback period P_{F}[1] and continues until the end time point of the pulse period PP. Each of the first feedback period P_{F}[1] and the second feedback period P_{F}[2] may include a plurality of waveform cycles CY.

The power supply controller may perform the above-described second feedback processing to determine the source frequency f for each of the plurality of designated phase periods DP within each of the plurality of waveform cycles CY in the first feedback period P_{F}[1]. The power supply controller may also determine the source frequency f for each phase period other than the plurality of designated phase periods DP within each of the plurality of waveform cycles CY in the first feedback period P_{F}[1] by interpolation using the source frequencies f for the plurality of designated phase periods DP.

The power supply controller may set the source frequency f for each phase period between the last designated phase period within the j-th waveform cycle CY in the first feedback period P_{F}[1] and the first designated phase period DP₁ within the (j+1)-th waveform cycle CY in the first feedback period P_{F}[1] to a value obtained by interpolation (for example, linear interpolation) using the source frequency f of the last designated phase period and the source frequency f of the first designated phase period DP₁. The number of designated phase periods in each of the plurality of waveform cycles CY in the first feedback period P_{F}[1] may be different. Also, in each of the plurality of waveform cycles CY in the first feedback period P_{F}[1], the temporal positions of the plurality of designated phase periods may be different.

As described above, source radio frequency power HF having a power level lower than the power level of the pulse of the source radio frequency power HF may be supplied during a period between the period in which a pulse of the source radio frequency power HF is supplied and the period in which the next pulse of the source radio frequency power HF is supplied. Hereinafter, the period during which the source radio frequency power HF having a power level lower than the power level of the pulse of the source radio frequency power HF is supplied is referred to as a LOW period. The source frequency f used in the LOW period may be constant or may be predetermined.

The first phase period PH₁ within the first waveform cycle CY in the first feedback period P_{F}[1] may be the first designated phase period DP₁ among the plurality of designated phase periods DP. Alternatively, the first phase period PH₁ within the first waveform cycle CY in the first feedback period P_{F}[1] need not be the first designated phase period DP₁ among the plurality of designated phase periods DP. In the latter case, the power supply controller may set the source frequency f for each phase period between the last time point in the LOW period and the first designated phase period DP₁ in the first feedback period P_{F}[1] to a value obtained by interpolation (for example, linear interpolation) using the source frequency f of the LOW period and the source frequency f of the first designated phase period DP₁ in the first feedback period P_{F}[1].

The power supply controller may also perform the above-described first feedback processing to determine the source frequency f for each of the plurality of designated phase periods DP within each of the plurality of waveform cycles CY in the second feedback period P_{F}[2]. The power supply controller may also determine the source frequency f for each of the phase periods other than the plurality of designated phase periods DP within each of the plurality of waveform cycles CY in the second feedback period P_{F}[2] by interpolation using the source frequencies f for the plurality of designated phase periods DP. Alternatively, the power supply controller may use, as the source frequencies f for the plurality of phase periods PH within each of the plurality of waveform cycles CY in the second feedback period P_{F}[2], the source frequencies f for the plurality of phase periods PH within the last waveform cycle CY in the immediately preceding first feedback period P_{F}[1].

The above-described feedback processing can also be utilized in the processing of determining the source frequency f for each of the plurality of phase periods PH in order to determine the plurality of designated phase periods DP. In this case, the processing for the designated phase period DPₘ in the above-described feedback processing is applied to the phase period PHₙ.

Although various example embodiments have been described above, various additions, omissions, substitutions, and changes may be made without being limited to the example embodiments described above. It is also possible to combine elements in different embodiments to form other embodiments.

Here, various example embodiments included in the present disclosure are described in [E1] to [E20] below.
[E1]

A plasma processing apparatus including:
a chamber;
a substrate support disposed in the chamber; and
a power supply system, including:
   a radio frequency power supply configured to supply source radio frequency power to generate plasma in the chamber;
   a bias power supply configured to repeatedly supply an electric bias to the substrate support at a time interval of a waveform cycle to attract ions from the plasma to a substrate on the substrate support; and
   a power supply circuitry,
the waveform cycle includes a plurality of phase periods, and the plurality of phase periods includes a plurality of designated phase periods of which a total number is less than a total number of the plurality of phase periods, and
the power supply circuitry is configured to:
   determine respective source frequencies of the source radio frequency power for the plurality of designated phase periods by adjusting the source frequency of the source radio frequency power for an m-th designated phase period among the plurality of designated phase periods within an i-th waveform cycle in a sequence of waveform cycles so as to suppress reflection of the source radio frequency power, based on a change in the source frequency for the m-th designated phase period and a change in a degree of reflection of the source radio frequency power prior to the i-th waveform cycle in the sequence; and
   determine respective source frequencies for phase periods, other than the plurality of designated phase periods, among the plurality of phase periods within the i-th waveform cycle by interpolation using the respective source frequencies for the plurality of designated phase periods.
[E2]

The plasma processing apparatus according to E1, wherein a phase of each of the plurality of designated phase periods in the waveform cycle is predetermined.
[E3]

The plasma processing apparatus according to E2, wherein the electric bias includes a voltage pulse periodically generated at a time interval equal to a time length of the waveform cycle,
the waveform cycle includes a first period during which the voltage pulse is in an OFF state, a second period following the first period during which the voltage pulse is in an ON state, and a third period following the second period during which the voltage pulse is in an OFF state, and
an interval of the plurality of designated phase periods in the second period is smaller than an interval of the plurality of designated phase periods in each of the first period and the third period.
[E4]

The plasma processing apparatus according to E3, wherein the interval of the plurality of designated phase periods in the third period is the same as or smaller than the interval of the plurality of designated phase periods in the first period.
[E5]

The plasma processing apparatus according to E3 or E4, wherein the voltage pulse has a set voltage level that is negative with respect to a reference voltage level,
the second period includes a first sub-period during which the voltage level of the voltage pulse changes from the reference voltage level to the set voltage level, a second sub-period during which the voltage level of the voltage pulse is at the set voltage level, and a third sub-period during which the voltage level of the voltage pulse changes from the set voltage level to the reference voltage level, and
an interval of the plurality of designated phase periods in the first sub-period, an interval of the plurality of designated phase periods in the second sub-period, and an interval of the plurality of designated phase periods in the third sub-period are different from each other.
[E6]

The plasma processing apparatus according to E1, wherein the power supply circuitry is configured to:
determine respective source frequencies for the plurality of phase periods by performing, in a preparation period before performing processing of determining the respective source frequencies for the plurality of designated phase periods, the same processing for the plurality of phase periods; and
determine the plurality of designated phase periods such that the larger a change in the source frequency in a section in the sequence of source frequencies obtained by smoothing the sequence of the respective source frequencies for the plurality of phase periods, the smaller an interval of the plurality of designated phase periods.
[E7]

The plasma processing apparatus according to any one of E1 to E6, wherein the power supply circuitry is configured to use, as the interpolation, linear interpolation.
[E8]

The plasma processing apparatus according to any one of E1 to E7, wherein the power supply circuitry is configured to, in response to determining, as a result of comparison between a degree of reflection in the m-th designated phase period among the plurality of designated phase periods within the i-th waveform cycle in the sequence and a first threshold value, that the degree of reflection is smaller than a predetermined amount, not change the source frequency for the m-th designated phase period until it is subsequently determined as a result of comparison between the degree of reflection in the m-th designated phase period in a waveform cycle after the i-th waveform cycle in the sequence and a second threshold value, that the degree of reflection is larger than the predetermined amount, and
the second threshold value is greater than the first threshold value.
[E9]

A power supply system including:
a radio frequency power supply configured to supply source radio frequency power to generate plasma in a chamber of a plasma processing apparatus;
a bias power supply configured to repeatedly supply an electric bias to a substrate support at a time interval of a waveform cycle to attract ions from the plasma to a substrate on the substrate support in the chamber; and
a power supply circuitry,
wherein the waveform cycle includes a plurality of phase periods, and the plurality of phase periods includes a plurality of designated phase periods of which a total number is less than a total number of the plurality of phase periods, and
the power supply circuitry is configured to:
   determine respective source frequencies of the source radio frequency power for the plurality of designated phase periods by adjusting the source frequency of the source radio frequency power for an m-th designated phase period among the plurality of designated phase periods within an i-th waveform cycle in a sequence of waveform cycles so as to suppress reflection of the source radio frequency power, based on a change in the source frequency for the m-th designated phase period and a change in a degree of reflection of the source radio frequency power prior to the i-th waveform cycle in the sequence; and
   determine respective source frequencies for phase periods, other than the plurality of designated phase periods, among the plurality of phase periods within the i-th waveform cycle by interpolation using the respective source frequencies for the plurality of designated phase periods.
[E10]

The power supply system according to E9, wherein a phase of each of the plurality of designated phase periods in the waveform cycle is predetermined.
[E11]

The power supply system according to E10, wherein the electric bias includes a voltage pulse periodically generated at a time interval equal to a time length of the waveform cycle,
the waveform cycle includes a first period during which the voltage pulse is in an OFF state, a second period following the first period during which the voltage pulse is in an ON state, and a third period following the second period during which the voltage pulse is in an OFF state, and
an interval of the plurality of designated phase periods in the second period is smaller than an interval of the plurality of designated phase periods in each of the first period and the third period.
[E12]

The power supply system according to E11, wherein the interval of the plurality of designated phase periods in the third period is the same as or smaller than the interval of the plurality of designated phase periods in the first period.
[E13]

The power supply system according to E11, wherein the voltage pulse has a set voltage level that is negative with respect to a reference voltage level,
the second period includes a first sub-period during which the voltage level of the voltage pulse changes from the reference voltage level to the set voltage level, a second sub-period during which the voltage level of the voltage pulse is at the set voltage level, and a third sub-period during which the voltage level of the voltage pulse changes from the set voltage level to the reference voltage level, and
an interval of the plurality of designated phase periods in the first sub-period, an interval of the plurality of designated phase periods in the second sub-period, and an interval of the plurality of designated phase periods in the third sub-period are different from each other.
[E14]

The power supply system according to E9, wherein the power supply circuitry is configured to:
determine respective frequencies of the radio frequency power for the plurality of phase periods by performing, in a preparation period before performing processing of determining the respective frequencies of the radio frequency power for the plurality of designated phase periods, the same processing for the plurality of phase periods; and
determine the plurality of designated phase periods such that the larger a change in the frequency of the radio frequency power in a section in the sequence of frequencies of the radio frequency power obtained by smoothing the sequence of the respective frequencies of the radio frequency power for the plurality of phase periods, the smaller an interval of the plurality of designated phase periods.
[E15]

The power supply system according to E9, wherein the power supply circuitry is configured to use, as the interpolation, linear interpolation.
[E16]

The power supply system according to E9, wherein the power supply circuitry is configured to, in response to determining, as a result of comparison between a degree of reflection in the m-th designated phase period among the plurality of designated phase periods within the i-th waveform cycle in the sequence and a first threshold value that the degree of reflection is smaller than a predetermined amount, not change the frequency of the radio frequency power for the m-th designated phase period until it is subsequently determined as a result of comparison between the degree of reflection in the m-th designated phase period in a waveform cycle after the i-th waveform cycle in the sequence and a second threshold value that the degree of reflection is larger than a predetermined amount, and
the second threshold value is greater than the first threshold value.
[E17]

A control method including:
(a) supplying source radio frequency power from a radio frequency power supply to generate plasma in a chamber of a plasma processing apparatus; and
(b) repeatedly supplying an electric bias to a substrate support at a time interval of a waveform cycle to attract ions from the plasma to a substrate on the substrate support disposed in the chamber,
wherein the waveform cycle includes a plurality of phase periods, and the plurality of phase periods includes a plurality of designated phase periods of which a total number is less than a total number of the plurality of phase periods,
the (a) includes:
   (c) determining respective source frequencies of the source radio frequency power for the plurality of designated phase periods by adjusting the source frequency of the source radio frequency power for an m-th designated phase period among the plurality of designated phase periods within an i-th waveform cycle in a sequence of waveform cycles so as to suppress reflection of the source radio frequency power, based on a change in the source frequency for the m-th designated phase period and a change in a degree of reflection of the source radio frequency power prior to the i-th waveform cycle in the sequence; and
   (d) determining respective source frequencies for phase periods, other than the plurality of designated phase periods, among the plurality of phase periods within the i-th waveform cycle by interpolation using the respective source frequencies for the plurality of designated phase periods.
[E18]

The control method according to E17, wherein a phase of each of the plurality of designated phase periods in the waveform cycle is predetermined.
[E19]

The control method according to E18, wherein the electric bias includes a voltage pulse periodically generated at a time interval equal to a time length of the waveform cycle,
the waveform cycle includes a first period during which the voltage pulse is in an OFF state, a second period following the first period during which the voltage pulse is in an ON state, and a third period following the second period during which the voltage pulse is in an OFF state, and
an interval of the plurality of designated phase periods in the second period is smaller than an interval of the plurality of designated phase periods in each of the first period and the third period.
[E20]

The control method according to E19, wherein the interval of the plurality of designated phase periods in the third period is the same as or smaller than the interval of the plurality of designated phase periods in the first period.

From the above description, it will be understood that various embodiments of the present disclosure have been described herein for purposes of illustration, and that various modifications may be made without departing from the scope and spirit of the present disclosure. Accordingly, the various embodiments disclosed herein are not intended to be limiting, and the true scope and spirit are indicated by the appended claims.

What is claimed is:

1. A plasma processing apparatus comprising:
a chamber;
a substrate support disposed in the chamber; and
a power supply system, including:
a radio frequency power supply configured to supply radio frequency power to generate plasma in the chamber;
a bias power supply configured to repeatedly supply an electric bias to the substrate support at a time interval of a waveform cycle to attract ions from the plasma to a substrate on the substrate support; and
a power supply circuitry,
the waveform cycle includes a plurality of phase periods, and the plurality of phase periods includes a plurality of designated phase periods of which a total number is less than a total number of the plurality of phase periods, and
the power supply circuitry is configured to:
determine respective frequencies of the radio frequency power for the plurality of designated phase periods by adjusting the frequency of the radio frequency power for an m-th designated phase period among the plurality of designated phase periods within an i-th waveform cycle in a sequence of waveform cycles so as to suppress reflection of the radio frequency power, based on a change in the frequency of the radio frequency power for the m-th designated phase period and a change in a degree of reflection of the radio frequency power prior to the i-th waveform cycle in the sequence; and
determine respective frequencies of the radio frequency power for phase periods, other than the plurality of designated phase periods, among the plurality of phase periods within the i-th waveform cycle by interpolation using the respective frequencies of the radio frequency power for the plurality of designated phase periods.

2. The plasma processing apparatus according to claim 1, wherein a phase of each of the plurality of designated phase periods in the waveform cycle is predetermined.

3. The plasma processing apparatus according to claim 2, wherein the electric bias includes a voltage pulse periodically generated at a time interval equal to a time length of the waveform cycle,
the waveform cycle includes a first period during which the voltage pulse is in an OFF state, a second period following the first period during which the voltage pulse is in an ON state, and a third period following the second period during which the voltage pulse is in an OFF state, and
an interval of the plurality of designated phase periods in the second period is smaller than an interval of the plurality of designated phase periods in each of the first period and the third period.

4. The plasma processing apparatus according to claim 3, wherein the interval of the plurality of designated phase periods in the third period is the same as or smaller than the interval of the plurality of designated phase periods in the first period.

5. The plasma processing apparatus according to claim 3, wherein the voltage pulse has a set voltage level that is negative with respect to a reference voltage level,
the second period includes a first sub-period during which the voltage level of the voltage pulse changes from the reference voltage level to the set voltage level, a second sub-period during which the voltage level of the voltage pulse is at the set voltage level, and a third sub-period during which the voltage level of the voltage pulse changes from the set voltage level to the reference voltage level, and
an interval of the plurality of designated phase periods in the first sub-period, an interval of the plurality of designated phase periods in the second sub-period, and an interval of the plurality of designated phase periods in the third sub-period are different from each other.

6. The plasma processing apparatus according to claim 1, wherein the power supply circuitry is configured to:
determine respective frequencies of the radio frequency power for the plurality of phase periods by performing, in a preparation period before performing processing of determining the respective frequencies of the radio frequency power for the plurality of designated phase periods, the same processing for the plurality of phase periods; and
determine the plurality of designated phase periods such that the larger a change in the frequency of the radio frequency power in a section in the sequence of frequencies of the radio frequency power obtained by smoothing the sequence of the respective frequencies of the radio frequency power for the plurality of phase periods, the smaller an interval of the plurality of designated phase periods.

7. The plasma processing apparatus according to claim 1, wherein the power supply circuitry is configured to use, as the interpolation, linear interpolation.

8. The plasma processing apparatus according to claim 1, wherein the power supply circuitry is configured to, in response to determining, as a result of comparison between a degree of reflection in the m-th designated phase period among the plurality of designated phase periods within the i-th waveform cycle in the sequence and a first threshold value that the degree of reflection is smaller than a predetermined amount, not change the frequency of the radio frequency power for the m-th designated phase period until it is subsequently determined as a result of comparison between the degree of reflection in the m-th designated phase period in a waveform cycle after the i-th waveform cycle in the sequence and a second threshold value that the degree of reflection is larger than the predetermined amount, and
the second threshold value is greater than the first threshold value.

9. A power supply system comprising:
a radio frequency power supply configured to supply radio frequency power to generate plasma in a chamber of a plasma processing apparatus;
a bias power supply configured to repeatedly supply an electric bias to a substrate support at a time interval of a waveform cycle to attract ions from the plasma to a substrate on the substrate support in the chamber; and
a power supply circuitry,
wherein the waveform cycle includes a plurality of phase periods, and the plurality of phase periods includes a plurality of designated phase periods of which a total number is less than a total number of the plurality of phase periods, and
the power supply circuitry is configured to:
determine respective frequencies of the radio frequency power for the plurality of designated phase periods by adjusting the frequency of the radio frequency power for an m-th designated phase period among the plurality of designated phase periods within an i-th waveform cycle in a sequence of waveform cycles so as to suppress reflection of the radio frequency power, based on a change in the frequency of the radio frequency power for the m-th designated phase period and a change in a degree of reflection of the radio frequency power prior to the i-th waveform cycle in the sequence; and
determine respective frequencies of the radio frequency power for phase periods, other than the plurality of designated phase periods, among the plurality of phase periods within the i-th waveform cycle by interpolation using the respective frequencies of the radio frequency power for the plurality of designated phase periods.

10. The power supply system according to claim 9, wherein a phase of each of the plurality of designated phase periods in the waveform cycle is predetermined.

11. The power supply system according to claim 10, wherein the electric bias includes a voltage pulse periodically generated at a time interval equal to a time length of the waveform cycle,
the waveform cycle includes a first period during which the voltage pulse is in an OFF state, a second period following the first period during which the voltage pulse is in an ON state, and a third period following the second period during which the voltage pulse is in an OFF state, and
an interval of the plurality of designated phase periods in the second period is smaller than an interval of the plurality of designated phase periods in each of the first period and the third period.

12. The power supply system according to claim 11, wherein the interval of the plurality of designated phase periods in the third period is the same as or smaller than the interval of the plurality of designated phase periods in the first period.

13. The power supply system according to claim 11, wherein the voltage pulse has a set voltage level that is negative with respect to a reference voltage level,
the second period includes a first sub-period during which the voltage level of the voltage pulse changes from the reference voltage level to the set voltage level, a second sub-period during which the voltage level of the voltage pulse is at the set voltage level, and a third sub-period during which the voltage level of the voltage pulse changes from the set voltage level to the reference voltage level, and
an interval of the plurality of designated phase periods in the first sub-period, an interval of the plurality of designated phase periods in the second sub-period, and an interval of the plurality of designated phase periods in the third sub-period are different from each other.

14. The power supply system according to claim 9, wherein the power supply circuitry is configured to:
determine respective frequencies of the radio frequency power for the plurality of phase periods by performing, in a preparation period before performing processing of determining the respective frequencies of the radio frequency power for the plurality of designated phase periods, the same processing for the plurality of phase periods; and
determine the plurality of designated phase periods such that the larger a change in the frequency of the radio frequency power in a section in the sequence of frequencies of the radio frequency power obtained by smoothing the sequence of the respective frequencies of the radio frequency power for the plurality of phase periods, the smaller an interval of the plurality of designated phase periods.

15. The power supply system according to claim 9, wherein the power supply circuitry is configured to use, as the interpolation, linear interpolation.

16. The power supply system according to claim 9, wherein the power supply circuitry is configured to, in response to determining, as a result of comparison between a degree of reflection in the m-th designated phase period among the plurality of designated phase periods within the i-th waveform cycle in the sequence and a first threshold value that the degree of reflection is smaller than a predetermined amount, not change the frequency of the radio frequency power for the m-th designated phase period until it is subsequently determined as a result of comparison between the degree of reflection in the m-th designated phase period in a waveform cycle after the i-th waveform cycle in the sequence and a second threshold value that the degree of reflection is larger than a predetermined amount, and
the second threshold value is greater than the first threshold value.

17. A control method comprising:
(a) supplying radio frequency power from a radio frequency power supply to generate plasma in a chamber of a plasma processing apparatus; and
(b) repeatedly supplying an electric bias to a substrate support at a time interval of a waveform cycle to attract ions from the plasma to a substrate on the substrate support disposed in the chamber,
wherein the waveform cycle includes a plurality of phase periods, and the plurality of phase periods includes a plurality of designated phase periods of which a total number is less than a total number of the plurality of phase periods, and
the (a) includes:
(c) determining respective frequencies of the radio frequency power for the plurality of designated phase periods by adjusting the frequency of the radio frequency power for an m-th designated phase period among the plurality of designated phase periods within an i-th waveform cycle in a sequence of waveform cycles so as to suppress reflection of the radio frequency power, based on a change in the frequency of the radio frequency power for the m-th designated phase period and a change in a degree of reflection of the radio frequency power prior to the i-th waveform cycle in the sequence; and
(d) determining respective frequencies of the radio frequency power for phase periods, other than the plurality of designated phase periods, among the plurality of phase periods within the i-th waveform cycle by interpolation using the respective frequencies of the radio frequency power for the plurality of designated phase periods.

18. The control method according to claim 17, wherein a phase of each of the plurality of designated phase periods in the waveform cycle is predetermined.

19. The control method according to claim 18, wherein the electric bias includes a voltage pulse periodically generated at a time interval equal to a time length of the waveform cycle,
the waveform cycle includes a first period during which the voltage pulse is in an OFF state, a second period following the first period during which the voltage pulse is in an ON state, and a third period following the second period during which the voltage pulse is in an OFF state, and
an interval of the plurality of designated phase periods in the second period is smaller than an interval of the plurality of designated phase periods in each of the first period and the third period.

20. The control method according to claim 19, wherein the interval of the plurality of designated phase periods in the third period is the same as or smaller than the interval of the plurality of designated phase periods in the first period.
